(19) United States
(12) Patent Application Publication
(10) Pub. No.: US 2014/0151712 A1
(43) Pub. Date: Jun. 5, 2014

(54) ENHANCEMENT-MODE HIGH ELECTRON MOBILITY TRANSISTOR STRUCTURE AND METHOD OF MAKING SAME

(71) Applicant: IQE, KC, LLC, Taunton, MA (US)

(72) Inventors: Yu Cao, Norwood, MA (US); Oleg Laboutin, South Easton, MA (US); Wayne Johnson, Easton, MA (US)

(21) Appl. No.: 13/912,834

(22) Filed: Jun. 7, 2013

Related U.S. Application Data
(60) Provisional application No. 61/656,882, filed on Jun. 7, 2012.

(51) Int. Cl. H01L 29/778; H01L 29/66

(52) U.S. Cl. CPC H01L 29/7787; H01L 29/66431
USPC 257/76; 438/172

(57) ABSTRACT

An epitaxial structure, such as an enhancement-mode high electron mobility transistor (HEMT) includes a first barrier layer over an aluminum gallium nitride channel layer. The first barrier layer is formed at a first temperature and is overlaid by a second barrier layer formed at a second temperature that is lower than that of the first temperature. The first barrier layer acts as an etch stop when forming a gate recess in the second barrier layer by a wet or dry etching.

This application claims the benefit of U.S. Provisional Application No. 61/656,882, filed on Jun. 7, 2012, the teachings of which are incorporated herein by reference in their entirety.

### BACKGROUND OF THE INVENTION

Enhancement-mode (E-mode) high electron-mobility transistors (HEMTs), commonly employ a gate recess in the barrier layer of the transistor in order to obtain the desired threshold, or “turn-on” voltage, V_{T}, at which the HEMT begins to conduct on-state current. Dry etching, such as reactive ion etching (RIE) or inductively coupled plasma (ICP) etching, is typically employed to fabricate the gate recess in HEMTs. However, V_{T} depends, in part, upon the thickness of the barrier layer between the gate electrode and channel layer of the HEMT. Also, RIE and ICP processes can degrade electron mobility in the channel layer. Furthermore, it is difficult to control vertical scaling by use of RIE or ICP because of the lack of an etch stop in the nitride materials employed to form the barrier layer of HEMTs.

Therefore, a need exists for a HEMT and a method of fabricating a HEMT that overcomes or minimizes the above-referenced problems.

### SUMMARY OF THE INVENTION

The invention is related to an epitaxial structure, such as is employed in a high electron mobility transistor (HEMT) and a method of forming the epitaxial structure, wherein the depth of the gate recess formed in the barrier layer can be controlled during fabrication of the epitaxial structure.

In one embodiment, the invention is an epitaxial structure, such as is employed in a HEMT, that includes a substrate, a buffer layer on the substrate wherein the buffer layer includes gallium nitride, a channel layer over the buffer layer consisting essentially of Inₓ Ga₁₋ₓN, where 0≦x≦1, and wherein the channel layer includes a 2-dimensional electron gas region distal to the buffer layer. A first barrier layer over the channel layer is formed at a first temperature, and a second barrier layer over the first barrier layer is formed at a second temperature that is lower than that of the first temperature, at which the first barrier layer is formed.

In one embodiment, the invention is a method of forming an epitaxial structure, such as is employed in a HEMT, and includes the steps of forming a substrate, forming a buffer layer on the substrate, forming a channel layer over the buffer layer, wherein the channel layer consists essentially of Inₓ Ga₁₋ₓ N, where 0>x>1. A first barrier layer is formed over the channel at a first temperature, and a second barrier layer is formed over the first barrier layer at a temperature lower than that of the first temperature, whereby a 2-dimensional electron gas region is formed in the channel layer distal to the buffer layer as a result of forming at least one of the first and second barrier layers. A recess is then formed in the second barrier layer.

This invention has several advantages. For example, the formation of a barrier layer formed at a relatively high temperature between the channel layer and a barrier layer formed at a relatively low temperature serves as an etch stop during wet etching of the low temperature barrier layer to form a gate recess in the epitaxial structure. Further, the relative thickness of the high temperature and low temperature barrier layers can be controlled to thereby ensure that the total thickness of the low-temperature and high-temperature barrier layer components is more than the critical thickness needed to introduce a 2-dimensional electron gas into the channel layer of the as-grown structure. In general, independent control of barrier thickness between the gate and channel layer can be employed to determine the threshold voltage of a resulting HEMT employing the epitaxial structure of the invention.

### BRIEF DESCRIPTION OF THE DRAWINGS

FIG. 1 is a schematic representation of an epitaxial structure of the invention.

FIG. 2 is a schematic representation of an enhancement mode (E-mode) HEMT structure of the invention.

FIG. 3 is a transmission electron microscopy (TEM) image of two barrier layers of an epitaxial structure of the invention grown by a method of the invention.

FIG. 4. is a cross section of barrier layers of an epitaxial structure of the invention.

### DETAILED DESCRIPTION OF THE INVENTION

The invention is directed to an epitaxial structure, such as an epitaxial structure employed in a high electron mobility transistor (HEMT) structure, that includes a first barrier layer that is formed at a first temperature, and a second barrier layer over the first barrel barrier layer formed a second temperature, lower than that of the first temperature, and to a method of forming such an epitaxial structure.

In one embodiment, the invention is an epitaxial structure, such as an enhancement mode (E-mode) high electron-mobility transistor (HEMT) structure. As understood by those of skill in the art, an epitaxial structure can contain many distinct layers that are, either collectively or individually, designed to achieve desired device characteristics. An epitaxial structure is typically formed over a substrate. Examples of substrate materials for GaN-based epitaxial structures include sapphire (Al₂O₃), silicon carbide (SiC), silicon (Si), gallium nitride (GaN), or aluminum nitride (AlN). For a GaN-based FET, such as a HEMT, a buffer layer with high electrical resistivity is typically formed over the substrate. For HEMT epitaxial structures, a channel layer is typically formed over the buffer layer and a barrier layer is typically formed over the channel layer. The barrier layer should be formed from a material with larger bandgap than the material used to form the channel layer. When the barrier layer and channel layer are formed using appropriate materials and methods, a large electron concentration can be developed in the channel layer adjacent to the barrier layer. The electrons in this region exhibit high mobility and this collective group of electrons is referred to as a 2-dimensional electron gas (2DEG). It should be noted that certain optional layers may be present or absent in a HEMT epitaxial structure depending on its design. Of particular note, a channel layer may not be employed and, if a large bandgap barrier layer is formed over a buffer layer with smaller bandgap, a 2DEG can be formed in the region of the buffer layer adjacent to the barrier layer. There may also be intervening layers between the channel layer and the barrier layer. A common example is a spacer layer formed directly on the channel layer and between the channel layer and barrier layer. Such a spacer layer can be used to enhance properties of the 2DEG such as electron mobility and electron concentration. For GaN-based HEMTs, a common structure employs a GaN buffer layer, GaN channel layer, AN spacer layer, and AlGaN barrier layer, although many permutations are possible. Suitable material properties (e.g., bandgap) for the respective layers of GaN-based epitaxial structures are known in the art.

It should be noted that when a layer is referred to as being “on” or “over” another layer or substrate, it can be directly on the layer or substrate, or an intervening layer also may be present. A layer that is “directly on” another layer or substrate means that no intervening layer is present. It should also be understood that when a layer is referred to as being “on” or “over” another layer or substrate, it may cover the entire layer or substrate, or a portion of the layer or substrate.

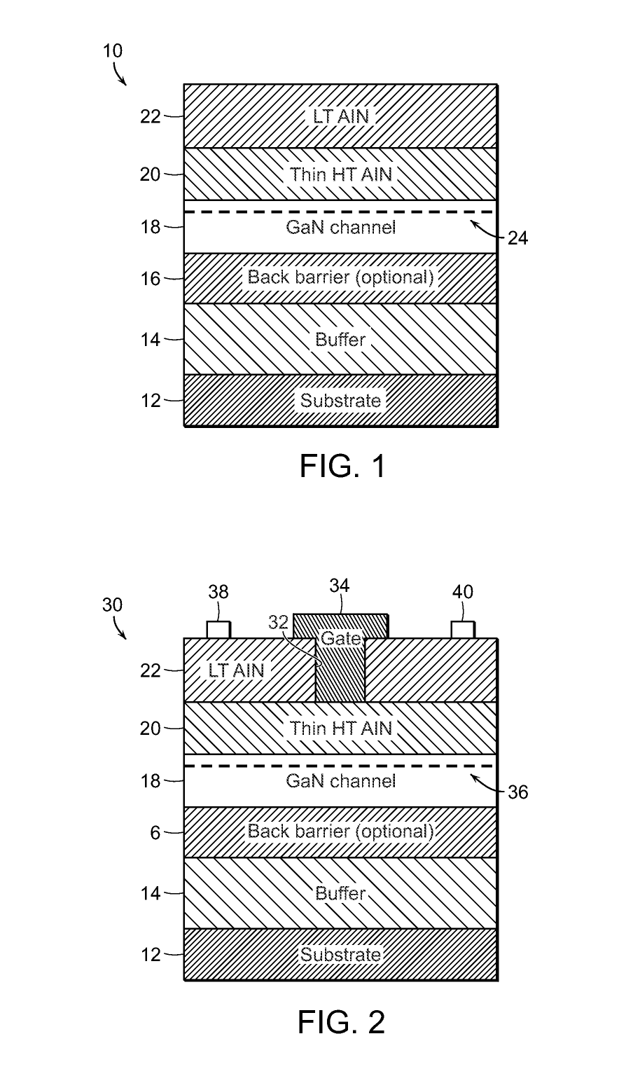

In one embodiment of the invention, shown in FIG. 1, epitaxial structure 10 includes substrate 12. Substrate 12 can be formed of a suitable material, such as is known in the art. Examples of suitable materials of substrate include silicon carbide (SiC), sapphire (Al₂O₃), silicon (Si) and gallium nitride (GaN).

Buffer layer 14 is deposited over substrate 12. Suitable materials of buffer layer 14 include those that are known in the art, such as GaN, aluminum nitride (AlGaN) and indium gallium nitride (InGaN). Buffer layer 14 is deposited by a suitable method, such as is known in the art. Examples of suitable methods of deposit of buffer layer include metal-organic chemical vapor deposition (MOCVD) and molecular beam epitaxy (MBE). Back barrier layer 16 is an optional component of the epitaxial structure of the invention. Back barrier layer 16 operates to help improve the confinement of electrons in the channel. Back barrier layer 16 can be fabricated by a suitable method, such as MOCVD or MBE, as is known in the art. Typically, suitable thicknesses of substrate 12, buffer layer 14 and back barrier 16 are typical of those known in the art. The average thickness of buffer layer 14 typically is in a range of between about 500 nm and about 10 μm, and that of back barrier layer 16 typically is in a range of between about 10 nm and about 1000 nm.

Channel layer 18 is formed over back barrier layer 16, if present. Otherwise, channel layer 18 is formed over buffer layer 14. Channel layer 18 is formed of InₓGa₁₋ₓN, where 0≦x≦1. Channel layer 18 is nominally-undoped. Typically, channel layer 18 is formed by a method known to those of skill in the art, such as metal-organic chemical vapor deposition (MOCVD) and beam epitaxy (MBE).

First aluminum nitride (AlN) barrier layer 20 is formed over the channel layer 18. As defined herein, a “barrier layer” is a layer in an epitaxial structure that has a wider band gap than the channel layer it overlays. First AlN barrier layer 20 is a crystalline material. Examples of suitable methods of forming first barrier layer 20 are known to those of skill in the art and include, for example, MOCVD or MBE. In one embodiment, first AlN barrier layer 20 is formed at a temperature in a range of between about 900° C. and about at 1300° C. Preferably, first barrier layer 20 is formed at a temperature in a range of between about 900° C. and about 1200° C. In one embodiment, first barrier layer 20 has a thickness in a range between about 0.5 nm and about 3.0 nm. In a preferred embodiment, the first barrier layer 20 has a thickness of the range between about 0.5 nm and about 2.0 nm.

Second barrier layer 22 is formed over first barrier layer 20. The second barrier layer 22 is a polycrystalline or an amorphous material and contains more material defects than first barrier layer 20. Preferably, first barrier layer 20 and second barrier layer 22 are formed of the same material, albeit at different temperatures. Second barrier layer 22 is formed at a temperature lower than that at which first barrier layer 20 was formed. In one embodiment, second barrier layer 22 is formed at a temperature in a range of between about 300° C. and about 800° C. Typically, the average thickness of second barrier layer 22 is in a range of between about 1.0 nm and about 10 nm. Preferably, the average thickness of second barrier layer 22 is in a range between about 1 nm and about 100 nm. 2-dimensional gas 26 is formed in channel layer 18 consequent to forming the barrier layers.

Preferably, the cumulative average thickness of first and second barrier layers is in a range of between about 5 nm and about 20 nm. Alternatively, the average cumulative thickness of first and second barrier layers is at least about 2 nm.

In a second embodiment of the invention shown in FIG. 2, E-mode structure 30 includes gate recess 32 and gate 34. The thickness of the first barrier layer 20 is sufficiently thin to prevent formation of 2-dimensional gas 36 immediately proximate to gate. However, in the access region (generally, between the gate and source and also between the gate and drain terminals), channel layer 18 is conductive because the total thickness of first barrier layer 20 and second barrier layer 22 is more than the critical thickness. An example of a typical critical thickness is about two nanometers (2 nm) when first barrier layer 20 and second barrier layer 22 are formed of aluminum nitride. Critical thicknesses associated with suitable barrier layer materials are well known to those skilled in the art.

As is known to those skilled in the art, source 38 and drain 40 terminals in electrical communication with second barrier layer are component parts of a HEMT, and are shown as components of the embodiment of the invention represented in FIG. 2. Gate recess 32 is formed by a suitable method, such as wet etching. Examples of suitable methods of dry-etching include reactive ion etching and inductively-coupled plasma etching.

### Exemplification

The following example represents a non-limiting embodiment of the invention.

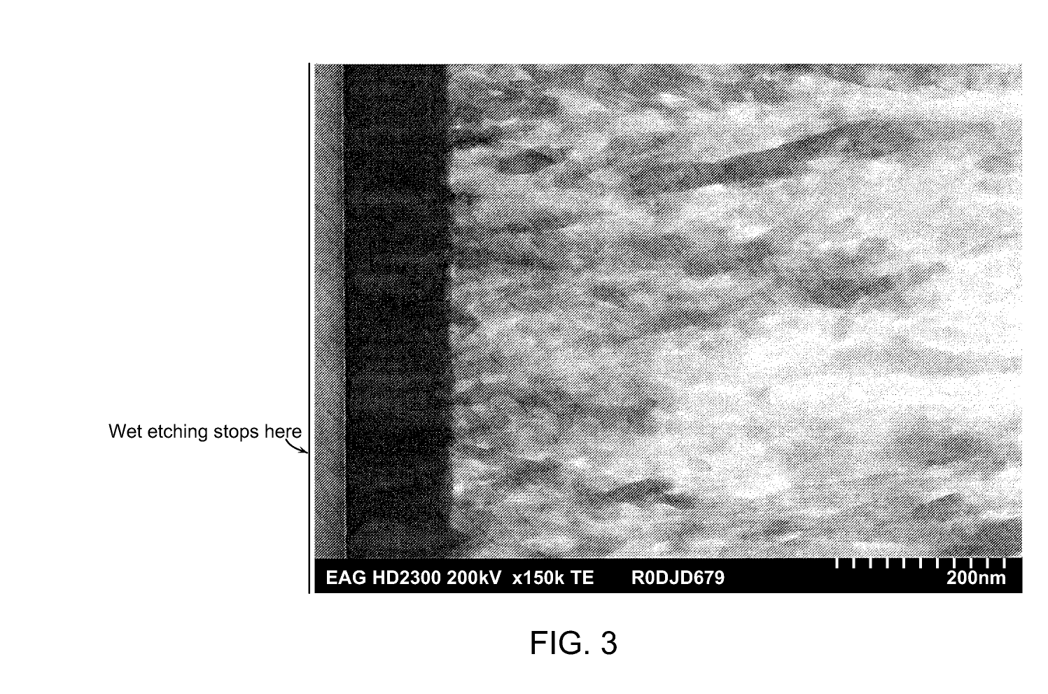

FIG. 3 shows the transmission electron microscopy (TEM) image of two barrier layers grown at low temperature and high temperature separately. The defective AlN grown at low temperature (LT AlN) shows disordered crystal orientation. The AlN grown at high temperature (HT AlN) is much more uniform.

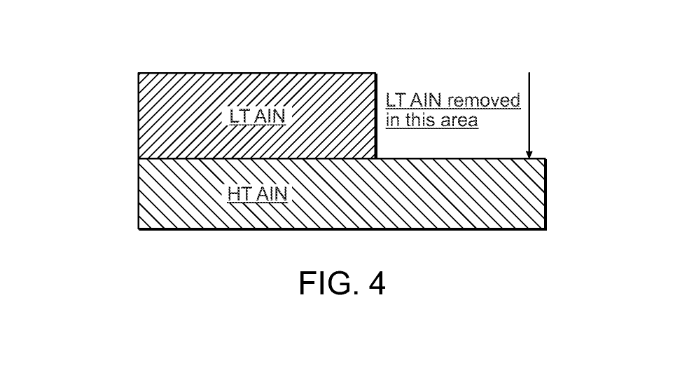

A wet etching test using room temperature potassium hydroxide (KOH) solution as the etchant was performed with the LT AlN and HT AlN separately. HT AlN is very resistive to KOH etching. After soaking the sample in KOH for 60 seconds, no obvious etching effect was observed. LT AlN reacted very actively with KOH. Within 15 seconds, 955 nm LT AlN was removed, which gave an etch rate of 63.7 nm/s. FIG. 4 shows that the wet etching stopped at the interface between LT AlN and HT AlN. This etch selectivity was believed to be an underlying property that enabled the structure of this invention.

### Equivalents

While this invention has been particularly shown and described with references to example embodiments thereof, it will be understood by those skilled in the art that various changes in form and details may be made therein without departing from the scope of the invention encompassed by the appended claims.

The teachings of all patents, published applications and references cited herein are incorporated by reference in their entirety.

What is claimed is:

1. An epitaxial structure, comprising:
a) a substrate;
b) a buffer layer on the substrate, the buffer layer including gallium nitride;
c) a channel layer over the buffer layer, the channel layer consisting essentially of InₓGa₁₋ₓN, where 0≦x≦1, and wherein the channel layer includes a 2-dimensional electron gas region distal to the buffer layer;
d) a first AlN barrier layer over the channel layer formed at a first temperature; and
e) a second AlN barrier layer on the first barrier layer, the second barrier being formed at a second temperature, the second temperature being lower than the first temperature, at which the first barrier layer is formed.

2. The epitaxial structure of claim 1, wherein the 2-dimensional electron gas region is distal to the buffer layer.

3. The epitaxial structure of claim 2, wherein the first barrier layer is formed at a temperature in a range of between about 900° C. and about 1,300° C.

4. The epitaxial structure of claim 3, wherein the second barrier layer is formed at a temperature in a range of between about 300° C. and about 800° C.

5. The epitaxial structure of claim 4, wherein the first barrier layer has a thickness in a range of between about 0.5 nm and about 2.0 nm.

6. The epitaxial structure of claim 5, wherein the second barrier layer has a thickness in a range of between about 1.0 nm and about 10 nm.

7. The epitaxial structure of claim 6, wherein the first barrier layer has a between about 0.5 nm and about 2 nm.

8. The epitaxial structure of claim 1, further including a back barrier layer between the channel layer and the buffer layer.

9. The epitaxial structure of claim 1, wherein the first barrier layer and the second barrier layer have a cumulative thickness of at least about 2 nm.

10. The epitaxial structure of claim 1, wherein the epitaxial structure is a high electron mobility transistor.

11. The epitaxial structure of claim 10, further including:
a) a source terminal in electrical communication with the second barrier layer;
b) a drain terminal in electrical communication with the second barrier layer; and
c) a gate terminal on the first barrier layer and between the source and drain terminals.

12. A method of forming a epitaxial structure, comprising the steps of:
a) forming a substrate;
b) forming a buffer layer on the substrate;
c) forming a channel layer over the buffer layer, the channel layer consisting essentially of InₓGa₁₋ₓN, where 0≦x≦1;
d) forming a first AlN barrier layer over the channel, the first barrier layer being formed at a first temperature;
e) forming a second AlN barrier layer over the first barrier layer, the second barrier being formed at a temperature lower than that of the first temperature, whereby a two dimensional electron gas forms between the channel and the first barrier layer, and whereby a 2-dimensional electron gas region is formed in the channel layer distal to the buffer layer as a result of forming at least one of the first and second barrier layers; and
f) forming a recess in the second barrier layer.

13. The method of claim 12, wherein the 2-dimensional electron gas region is distal to the buffer layer.

14. The method of claim 13, wherein the first barrier layer is of aluminum nitride and is formed at a temperature in a range between about 900° C. and about 1300° C.

15. The method of claim 14, where the second barrier layer is of aluminum nitride and is formed at a temperature in a range of between about 300° C. and about 900° C.

16. The method of claim 12, wherein the combined thickness of the first and second barrier layer is greater than about 2 nm.

17. The method of claim 12, wherein the recess in the second barrier layer is formed by wet etching.

18. The method of claim 12, wherein the recess in the second barrier layer is formed by dry etching.

19. The method of claim 18, wherein the dry etching includes reactive ion etching.

20. The method of claim 18, wherein the dry etching includes inductively-coupled plasma etching

21. The method of claim 12, further including the step of forming a back barrier layer between the buffer layer and the channel layer.

22. The method of claim 12, wherein the epitaxial structure formed is a high electron mobility transistor.

23. The method of claim 22, further including the steps of:
a) forming a source terminal in electrical communication with the second barrier layer;
b) forming a drain terminal in electrical communication with the second barrier layer; and
c) forming a gate terminal on the first barrier layer and between the source and drain terminals.
